(19) United States
(12) Patent Application Publication
(10) Pub. No.: US 2026/0005020 A1
(43) Pub. Date: Jan. 1, 2026

(54) INORGANIC RECONSTITUTION CARRIER PANEL

(71) Applicant: Intel Corporation, Santa Clara, CA (US)

(72) Inventors: Brandon C. MARIN, Gilbert, AZ (US); Srinivas Venkata Ramanuja PIETAMBARAM, Chandler, AZ (US); Jeremy D. ECTON, Gilbert, AZ (US); Hiroki TANAKA, Gilbert, AZ (US); Gang DUAN, Chandler, AZ (US)

(21) Appl. No.: 18/757,321

(22) Filed: Jun. 27, 2024

(51) Int. Cl. H01L 21/02; H01L 23/00; H01L 23/31; H01L 23/48; H01L 25/065

(52) U.S. Cl. CPC H01L 21/02422; H01L 21/02118; H01L 23/3157; H01L 23/481; H01L 24/24; H01L 25/0655; H01L 2224/24137

(57) ABSTRACT

Embodiments disclosed herein include an apparatus that comprises a substrate, where the substrate comprises a glass layer with a first surface, a second surface, and a sidewall surface. In an embodiment, a via is provided through a thickness of the substrate, and a first layer is on the substrate, where the first layer is over the first surface and the sidewall surface of the substrate. In an embodiment, the first layer comprises a first organic dielectric material. In an embodiment, a second layer is spaced apart from the substrate by the first layer, and the second layer comprises a second organic dielectric material. In an embodiment, a die is over the second surface of the substrate, where the die is hybrid bonded to the via.

### BACKGROUND

Electronics packaging substrates often include a core. Existing core materials include organic dielectrics that may include fiber reinforcement materials. As devices continue to become more complex, better performing core materials are desired. A package core that includes a solid glass layer is one potential option. Glass cores enable stiffer substrates, flatter surfaces, and can improve electrical performance.

However, the fragile nature of glass makes full-size glass panel edges extremely vulnerable to damage due to frequent contact of the edges during handling and processing. Designated toolsets that can handle and process glass panels need to be specially designed, and they are not widely available in the industry. This leads to a high technology improvement cost in order to enable a switch from organic core processing to glass core processing in a high volume manufacturing (HVM) environment.

### BRIEF DESCRIPTION OF THE DRAWINGS

FIG. 1A is a cross-sectional illustration of a package substrate with a glass core that is partially embedded within a mold layer, in accordance with an embodiment.

FIG. 1B is a cross-sectional illustration of a package substrate with a glass core that is covered by a mold layer and buildup layers, in accordance with an embodiment.

FIG. 1C is a cross-sectional illustration of a package substrate with a glass core that is partially embedded within a mold layer that includes a die with a width larger than the glass core that is bonded to the glass core, in accordance with an embodiment.

FIG. 1D is a cross-sectional illustration of a package substrate with a glass core that is partially embedded within a mold layer that includes a die with a width that is substantially equal to a width of the glass core, in accordance with an embodiment.

FIG. 1E is a cross-sectional illustration of a package substrate with a glass core that is partially embedded within a mold layer that includes a pair of dies that are electrically coupled together by routing in the mold layer, in accordance with an embodiment.

FIG. 1F is a cross-sectional illustration of a package substrate with a glass core that is partially embedded within a mold layer that includes a pair of dies that are electrically coupled together by a bridge over the mold layer, in accordance with an embodiment.

FIGS. 2A-2H are cross-sectional illustrations of a process for forming a package substrate with a partially embedded glass core, in accordance with an embodiment.

FIG. 3 is a flow diagram of a process for forming a package substrate with a partially embedded glass core, in accordance with an embodiment.

FIGS. 4A-4F are cross-sectional illustrations depicting a process for forming a package substrate with a partially embedded glass core from a reconstituted panel, in accordance with an embodiment.

FIG. 5 is a cross-sectional illustration of an electronic system with a package substrate that comprises a partially embedded glass core, in accordance with an embodiment.

FIG. 6 is a schematic of a computing device built in accordance with an embodiment.

### EMBODIMENTS OF THE PRESENT DISCLOSURE

Described herein are reconstituted glass panels with inorganic carriers for forming glass core packages, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, glass cores are an attractive option for some advanced packaging options. However, the fragile nature of the glass can lead to issues with panel level manufacturing. In order to safely handle glass panels, new high volume manufacturing (HVM) equipment may be necessary. This would lead to a significant retooling cost in order to accommodate the glass core panels.

Accordingly, embodiments disclosed herein may include reconstituted glass core panels. In such an embodiment, a plurality of glass cores (e.g., with a unit size form factor) are attached to a carrier. The carrier may be a reusable inorganic carrier. The glass cores are then overmolded with an organic dielectric molding material. For example, the molding material may be an epoxy or the like. The molding material may fill the gaps between the plurality of glass cores. This allows for the molding material to be provided over a top surface of the glass cores and sidewall surfaces of the glass cores. The bottom surface is pressed against the carrier, so the bottom surface may not be contacted by the molding material.

In an embodiment, the molding material protects the fragile glass cores throughout the rest of the panel assembly. For example, one or more buildup layers may be applied over the molding material. After the desired number of buildup layers are formed, the carrier may be removed to expose the bottom surface of the glass cores. In an embodiment, one or more dies may then be coupled to each of the glass cores. Stated differently, the dies may be directly over the glass cores without any intervening dielectric layers or the like. In some embodiments, the dies are hybrid bonded to the glass cores so that there is no solder or other intermediate interconnects between the dies and the glass cores as well.

In an embodiment, the reconstituted panel may be singulated with any suitable process. For example, a mechanical sawing process may be used to separate the plurality of glass cores from each other in order to form individual package substrates. In an embodiment, the cut lines for the singulation may be provided along the gaps between the glass cores. This allows for the singulation process to cut through the reconstituted panel without having to pass through any glass material. Accordingly, the singulation process may be simplified, and damage to the glass cores during singulation is minimized or eliminated. Singulating the reconstituted panel along the gaps between the glass cores also allows for portions of the molding material to remain along sidewalls of the glass core after singulation. As such, the glass core remains protected during subsequent processing operations.

It is to be appreciated that providing the die directly over the glass core reduces the number of buildup layers within the package substrate. For example, some embodiments may include a single buildup layer on the side of the glass core opposite from the die, or up to six buildup layers on the side of the glass core opposite from the die. Accordingly, electrical routing complexity may be minimized in some embodiments. Such simpler routing solutions may be suitable for certain product segments, such as client devices, mobile device, and/or the like.

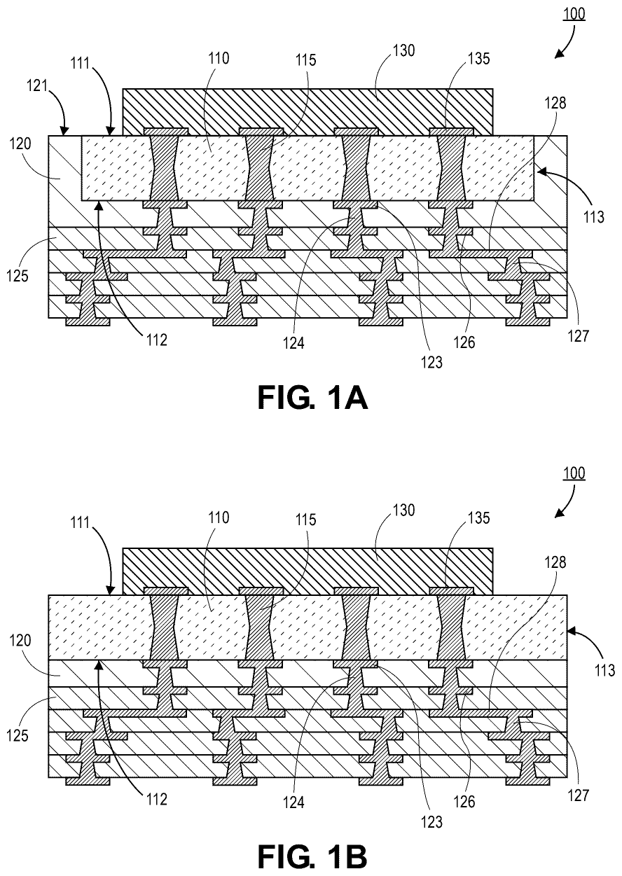

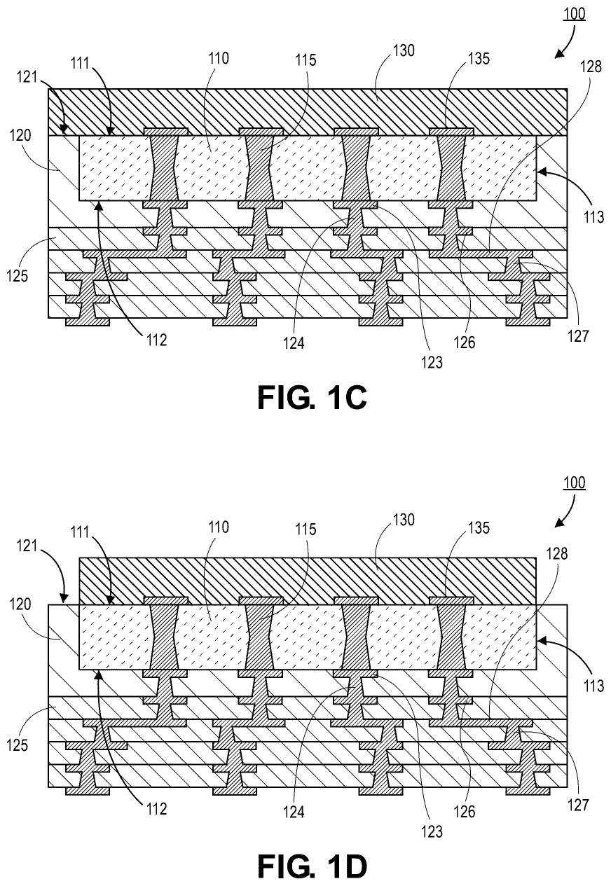

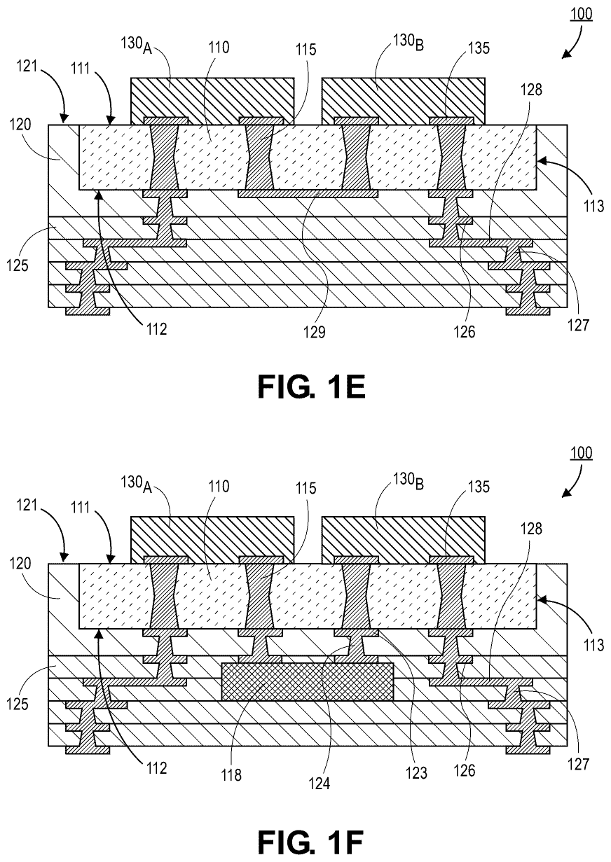

Referring now to FIGS. 1A-1F, a series of cross-sectional illustrations depicting package substrates 100 that include glass cores 110 is shown, in accordance with an embodiment. In some embodiments, the package substrates 100 may be referred to as single sided package substrates 100. This is because routing layers may be provided over a single side of the glass core 110. The die 130 may be directly coupled to the opposing side of the glass core 110 without any intervening routing layers. For example, the glass core 110 may be hybrid bonded to the die 130. As used herein, hybrid bonding may also sometimes be referred to as direct bonding. More generally, hybrid bonding or direct bonding may refer to an interconnect architecture where a first metal interconnect directly contacts a second metal interconnect without an intervening solder or the like.

Referring now to FIG. 1A, a cross-sectional illustration of a package substrate 100 is shown, in accordance with an embodiment. In an embodiment, the package substrate 100 may comprise a glass core 110. The glass core 110 may comprise a first surface 111 (i.e., a top surface), a second surface 112 (i.e., a bottom surface), and a sidewall surface 113 that couples the first surface 111 to the second surface 112. In an embodiment, the glass core 110 may comprise vias 115 that pass through a thickness of the glass core 110 between the first surface 111 and the second surface 112. In the illustrated embodiment, the vias 115 include an hourglass shaped cross-section. Though, the vias 115 may include a cross-section with a single taper, or the sidewalls of the vias 115 may be substantially vertical. The vias 115 may be formed with any suitable process, such as a laser assisted etching process, or the like.

In an embodiment, the glass core 110 may be substantially all glass. The glass core 110 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 110 may be distinguished from, for example, the “prepreg” or “FR4” core of a Printed Circuit Board (PCB) substrate which typically comprises glass fibers embedded in a resinous organic material, such as an epoxy.

The glass core 110 may have any suitable dimensions. In a particular embodiment, the glass core 110 may have a thickness that is approximately 50 μm or greater. For example, the thickness of the glass core 110 may be between approximately 50 μm and approximately 1.4 mm. Though, smaller or larger thicknesses may also be used. The glass core 110 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 110 (from an overhead plan view) may be between approximately 10 mm×10 mm and approximately 250 mm×250 mm. In an embodiment, the glass core 110 may have a first side that is perpendicular or orthogonal to a second side. In a more general embodiment, the glass core 110 may comprise a rectangular prism volume with sections (e.g., vias) removed and filled with other materials (e.g., metal, etc.).

The glass core 110 may comprise a single monolithic layer of glass. In other embodiments, the glass core 110 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 110 may each have a thickness less than approximately 50 μm. For example, discrete layers of glass in the glass core 110 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 110 may be any suitable glass formulation that has the necessary mechanical robustness and compatibility with semiconductor packaging manufacturing and assembly processes. For example, the glass core 110 may comprise aluminosilicate glass, borosilicate glass, alumino-borosilicate glass, silica, fused silica, or the like. In some embodiments, the glass core 110 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 110 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 110 may comprise at least 23 percent silicon (by weight) and at least 26 percent oxygen (by weight). In some embodiments, the glass core 110 may further comprise at least 5 percent aluminum (by weight).

In an embodiment, the glass core 110 may be at least partially embedded within a mold layer 120. The mold layer 120 may comprise any suitable organic dielectric material that can be dispensed over the glass core 110 so that the mold layer 120 conforms to surfaces of the glass core 110. For example, the mold layer 120 may comprise an epoxy, a buildup film, or the like. In some embodiments, the mold layer 120 may comprise inorganic reinforcement particles and/or fibers. For example, glass fibers or the like may be embedded within the mold layer 120. The mold layer 120 may be provided over the second surface 112 and the sidewall surfaces 113 of the glass core 110. That is, a total width of the mold layer 120 may be greater than a width of the glass core 110. Covering the sidewall surfaces 113 of the glass core 110 with portions of the mold layer 120 may help provide additional protection to the glass core 110. As such, the reliability of the package substrate 100 may be improved since the probability of cracking and/or otherwise damaging the fragile glass core 110 is reduced.

In an embodiment, a top surface 121 of the mold layer 120 may be substantially coplanar with the first surface 111 of the glass core 110. As used herein, substantially coplanar surfaces may refer to surfaces that are substantially along the same plane. As will be described in greater detail below, the top surface 121 of the mold layer 120 and the first surface 111 of the glass core 110 may be formed against the same underlying carrier. Since both the mold layer 120 and the glass core 110 are pressed against the same planar surface, the first surface 111 of the glass core 110 and the top surface 121 of the mold layer 120 will be mechanically aligned in a coplanar relationship with each other.

In an embodiment, pads 123 may be provided over the vias 115 of the glass core 110 along the second surface 112 of the glass core 110. The pads 123 may also be embedded within the mold layer 120. In an embodiment, vias 124 may pass through a portion of the mold layer 120 and be electrically coupled to the pads 123. In an embodiment, one or more buildup layers 125 may be provided on the mold layer 120 opposite from the top surface 121. In an embodiment, the buildup layers 125 may comprise organic dielectric material, such as buildup film or the like. Electrically conductive routing (e.g., pads 126, vias 127, traces 128, etc.) may be embedded within the buildup layers 125. The vias 124 may couple the pads 123 to the electrical routing within the buildup layers 125. The buildup layers 125 and the associated conductive routing may be fabricated with any suitable package assembly process, such as a semi-additive patterning (SAP) process or the like.

In an embodiment, a die 130 may be coupled to the glass core 110. In the particular embodiment shown in FIG. 1A, the die 130 is hybrid bonded to the glass core 110. For example, pads 135 of the die 130 may directly contact the vias 115. Though, in other embodiments, an intermediate pad (not shown) that is surrounded by a dielectric layer (not shown) may be provided between the pads 135 and the vias 115. As shown in FIG. 1A, the die 130 may directly contact the first surface 111 of the glass core 110. The use of a glass core 110 is beneficial for hybrid bonding due to the high planarity of the glass core 110. As such, fine pitch interconnects between the die 130 and the glass core 110 may be enabled in some embodiments. However, in other embodiments, the die 130 may be coupled to the vias 115 in the glass core 110 with any suitable first level interconnect (FLI) architecture, such as solder bumps or the like.

In an embodiment, the die 130 may have a width that is smaller than a width of the glass core 110. Accordingly, portions of the first surface 111 of the glass core 110 may remain exposed (i.e., not covered by the die 130) in some embodiments. In an embodiment, the die 130 may be any suitable type of die. For example, the die 130 may be a processor (e.g., a central processing unit (CPU), a graphics processing unit (GPU), etc.), a memory die, a communications die, or the like.

Referring now to FIG. 1B, a cross-sectional illustration of a package substrate 100 is shown, in accordance with an additional embodiment. In an embodiment, the package substrate 100 in FIG. 1B may be similar to the package substrate 100 in FIG. 1A, with the exception of the mold layer 120 and the buildup layers 125. Instead of providing a mold layer 120 that partially embeds the glass core 110, the mold layer 120 may only be provided over the second surface 112 of the glass core 110. That is, the sidewall surfaces 113 of the glass core 110 may be exposed and/or otherwise uncovered. The buildup layers 125 may also be narrower and match the width of the mold layer 120. Such an embodiment may be present when a singulation process (described in greater detail herein) cuts through a portion of the glass core 110.

Referring now to FIG. 1C, a cross-sectional illustration of a package substrate 100 with a glass core 110 is shown, in accordance with an additional embodiment. In an embodiment, the package substrate 100 in FIG. 1C is similar to the package substrate 100 in FIG. 1A, with the exception of the die 130. Instead of the die 130 having a width that is smaller than a width of the glass core 110, the width of the die 130 is greater than a width of the glass core 110. Accordingly, the entire first surface 111 of the glass core 110 may be covered by the die 130 in some embodiments. In the illustrated embodiment, the width of the die 130 may be substantially equal to the width of the mold layer 120. As such, the top surface 121 of the mold layer 120 may also be fully covered by the die 130.

Referring now to FIG. 1D, a cross-sectional illustration of a package substrate 100 with a glass core 110 is shown, in accordance with an additional embodiment. In an embodiment, the package substrate 100 in FIG. 1D is similar to the package substrate 100 in FIG. 1A, with the exception of the die 130. For example, the width of the die 130 may be substantially equal to the width of the glass core 110. In such an embodiment, the first surface 111 of the glass core 110 may be completely covered, while the top surface 121 of the mold layer 120 remains exposed.

Referring now to FIG. 1E, a cross-sectional illustration of a package substrate 100 with a glass core 110 is shown, in accordance with an additional embodiment. In an embodiment, the package substrate 100 in FIG. 1E is similar to the package substrate 100 in FIG. 1A, with the exception of there being a plurality of dies 130 provided over the glass core 110. For example, the package substrate 100 in FIG. 1E includes a first die 130_{A} and a second die 130_{B}. In an embodiment, the first die 130_{A} and the second die 130_{B} may be electrically coupled to each other. For example, a trace 129 on the second surface 112 of the glass core 110 may electrically couple a pair of vias 115 together, and each of the vias 115 may be hybrid bonded to different dies 130. While the trace 129 is shown as being within the mold layer 120 in FIG. 1E, other embodiments may include electrical coupling between the first die 130_{A} and the second die 130_{B} that occurs within the one or more of the buildup layers 125. In the illustrated embodiment, the first die 130_{A} and the second die 130_{B} may both be entirely within a footprint of the glass core 110. Though, in other embodiments, one or both of the first die 130_{A} and the second die 130_{B} may extend over the mold layer 120.

Referring now to FIG. 1F, a cross-sectional illustration of a package substrate 100 with a glass core 110 is shown, in accordance with an additional embodiment. The package substrate 100 in FIG. 1F may be similar to the package substrate 100 in FIG. 1E, with the exception of the electrical coupling between the first die 130_{A} and the second die 130_{B}. Instead of a trace 129, an embedded bridge 118 is provided within the buildup layers 125. The bridge 118 may comprise high density electrical routing (not shown) that provides electrical coupling between the first die 130_{A} and the second die 130_{B}. In an embodiment, the bridge 118 may comprise silicon, glass, or the like.

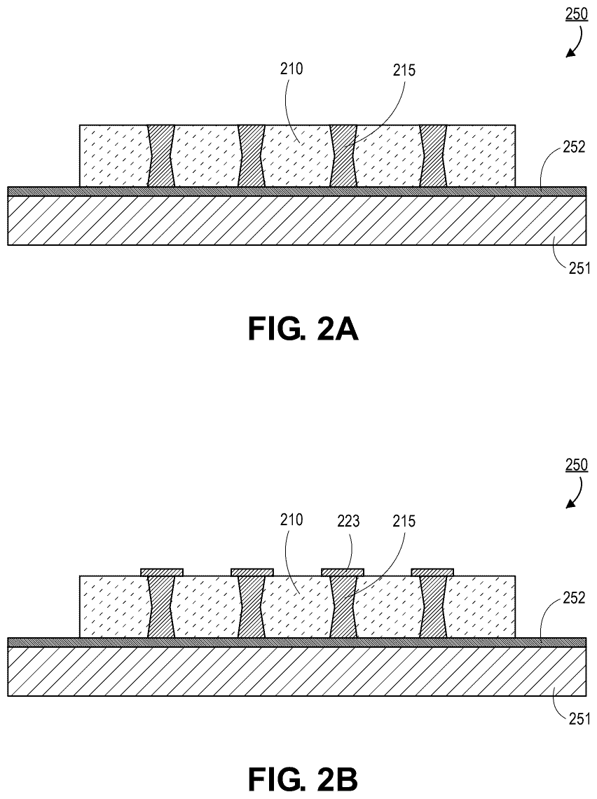

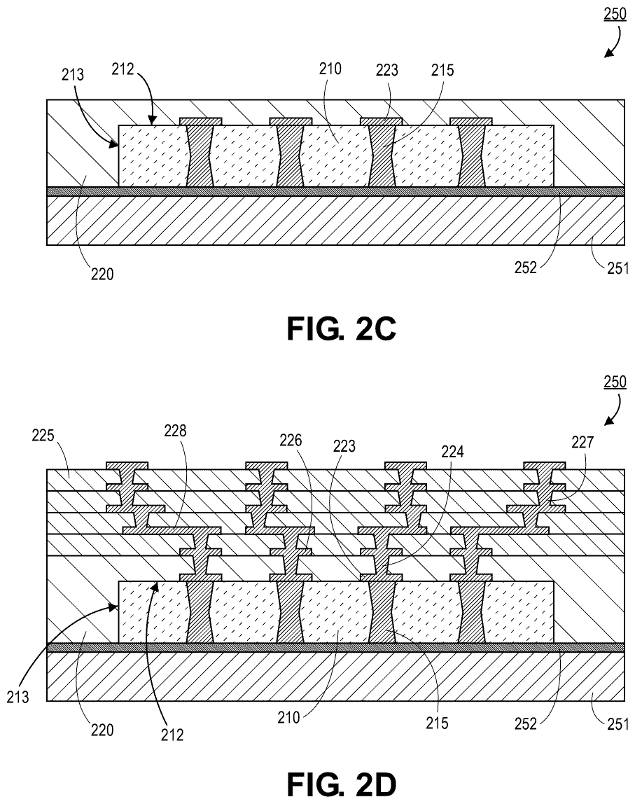

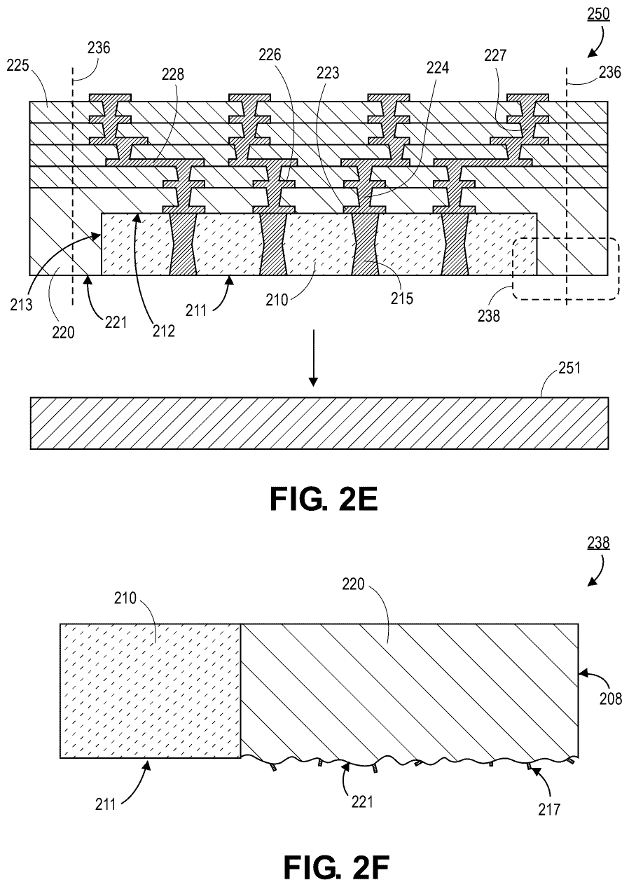

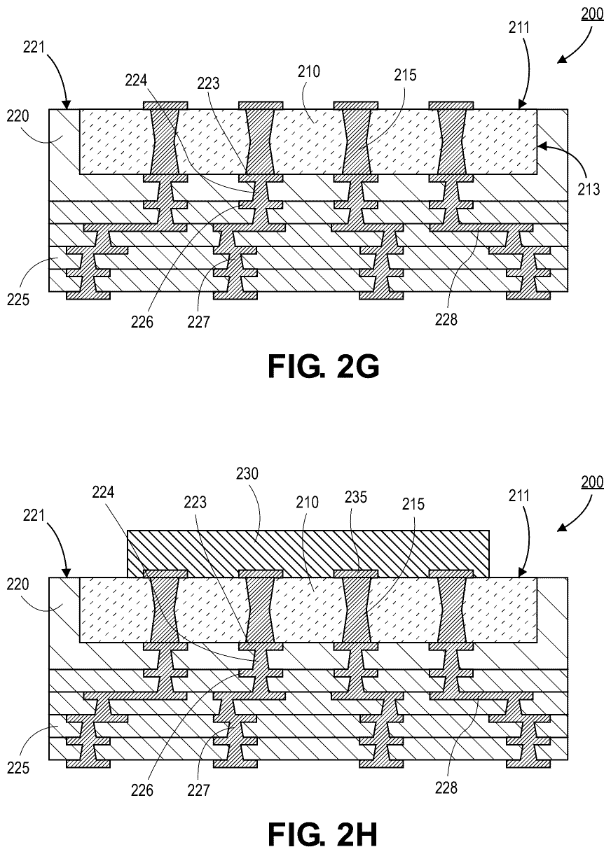

Referring now to FIGS. 2A-2H, a series of cross-sectional illustrations depicting a process for forming a package substrate 200 with a glass core 210 is shown, in accordance with an embodiment. In an embodiment, the package substrate 200 is formed through the use of a carrier and a reconstituted panel. The carrier may cover a surface of the glass core 210 so that routing layers may be provided on only one side of the glass core 210. The package substrate 200 may be similar to the package substrate 100 shown in FIG. 1A. Though, it is to be appreciated that any of the package substrates described in greater detail herein may be formed with a process similar to the one described in FIGS. 2A-2H with slight modifications.

Referring now to FIG. 2A, a cross-sectional illustration of a reconstituted panel 250 at a stage of manufacture is shown, in accordance with an embodiment. In an embodiment, the reconstituted panel 250 may comprise a glass core 210 that is attached to a carrier 251. For example, an adhesive layer 252 or the like may be used to couple the glass core 210 to the carrier 251. In an embodiment, the carrier 251 may comprise an inorganic material, such as a metal plate, a glass plate, a ceramic plate, or the like. In an embodiment, the glass core 210 may be similar to any of the glass cores described in greater detail herein. In an embodiment, vias 215 may be formed through the glass core 210. The vias 215 may be similar to any of the through glass vias described in greater detail herein.

Referring now to FIG. 2B, a cross-sectional illustration of the reconstituted panel 250 after pads 223 are formed over the top surface of the glass core 210 is shown, in accordance with an embodiment. The pads 223 may be formed with a plating and patterning process or the like. The pads 223 may be aligned over the vias 215. Though, in other embodiments, the pads 223 may be omitted.

Referring now to FIG. 2C, a cross-sectional illustration of the reconstituted panel 250 after a mold layer 220 is applied over the glass core 210 is shown, in accordance with an embodiment. In an embodiment, the mold layer 220 may be an organic dielectric material, such as an epoxy, a buildup film, or the like. In an embodiment, the mold layer 220 may cover a second surface 212 of the glass core 210 and sidewall surfaces 213 of the glass core 210. The mold layer 220 may also contact the adhesive layer 252 over the carrier 251. While referred to as “mold layer 220”, it is to be appreciated that the mold layer 220 may also be applied with a lamination process or any other suitable process.

Referring now to FIG. 2D, a cross-sectional illustration of the reconstituted panel 250 after one or more buildup layers 225 are formed over the mold layer 220 is shown, in accordance with an embodiment. In the illustrated embodiment, four buildup layers 225 are shown as one example. Though, embodiments may include any number of buildup layers 225. For example, there may be up to six buildup layers 225 provided over the mold layer 220 in some embodiments.

In an embodiment, the buildup layers 225 may comprise an organic dielectric material, such as a buildup film or the like. In an embodiment, the buildup layers 225 may comprise a different material than the mold layer 220. Though, in other embodiments, the mold layer 220 and the buildup layers 225 may comprise the same or similar material. For example, the mold layer 220 and the buildup layers 225 may both comprise a buildup film in some embodiments.

In an embodiment, electrically conductive routing may be provide in the buildup layers 225. For example, pads 226, vias 227, traces 228, and the like may be embedded within one or more of the buildup layers 225. The buildup layers 225 and the electrically conductive routing may be formed with any suitable process, such as an SAP process or the like. In an embodiment, the electrically conductive routing of the buildup layers 225 may be electrically coupled to the pads 223 (or the vias 215 in the glass core 210) by vias 224 that pass through a portion of the mold layer 220.

Referring now to FIG. 2E, a cross-sectional illustration of the reconstituted panel 250 after the carrier 251 is removed is shown, in accordance with an embodiment. In an embodiment, the carrier 251 may be removed by deactivating the adhesive layer 252. For example, a thermal release, an ultraviolet (UV) exposure release, a laser release, or the like may be used in order to deactivate the adhesive layer 252. Removal of the carrier 251 exposes a first surface 211 of the glass core 210 and a surface 221 of the mold layer 220. Since the mold layer 220 and the glass core 210 were both pressed against the same planar surface of the carrier 251, the first surface 211 of the glass core 210 and the surface 221 of the mold layer 220 may be substantially coplanar with each other.

Referring now to FIG. 2F, a zoomed in cross-sectional illustration of region 238 in FIG. 2E is shown, in accordance with an embodiment. In an embodiment, the region 238 illustrates a profile of the first surface 211 of the glass core 210 and the surface 221 of the mold layer 220. As shown, a surface roughness of the first surface 211 of the glass core 210 may be lower than a surface roughness of the surface 221 of the mold layer 220. For example, the surface 221 of the mold layer 220 may be non-planar, scalloped, and/or the like. The surface 221 of the mold layer 220 may also exhibit thermal damage or the like.

The increased surface roughness and/or thermal damage may be due, at least in part, to the stimulus applied to release the carrier 251. More particularly, the surface 221 of the mold layer 220 that was pressed against the carrier 251 may have a different structure than a sidewall surface 208 of the mold layer 220 due to damage from the release process. For example, the sidewall surface 208 may have a lower surface roughness, and there may not be any thermal damage along the sidewall surface 208. Further, the release process may result in the protrusion of reinforcement features 217 from the surface 221 of the mold layer 220. For example, the reinforcement features 217 may comprise inorganic particles or fibers, such as glass fibers.

Referring now to FIG. 2G, a cross-sectional illustration of a package substrate 200 that is singulated from the reconstituted panel 250 is shown, in accordance with an embodiment. In an embodiment, singulation may occur along the cut lines 236 shown in FIG. 2E. The cut lines 236 may be outside of the glass core 210. Accordingly, portions of the mold layer 220 remain along the sidewall surfaces 213 of the glass core 210. Further, the singulation process may not need to pass through any glass, which further protects the glass core 210 from damage and makes the singulation process less complex. The singulation process may include a mechanical sawing process, a laser ablation process, an etching process, or the like.

Referring now to FIG. 2H, a cross-sectional illustration of the package substrate 200 after a die 230 is mounted to the glass core 210 is shown, in accordance with an embodiment. In the illustrated embodiment, pads 235 of the die 230 are hybrid bonded to the vias 215 of the glass core 210. Accordingly, there may not be any routing layers between the die 230 and the glass core 210 in some embodiments. In other embodiments, the die 230 may be coupled to the vias 215 with any suitable FLI architecture, such as solder balls or the like.

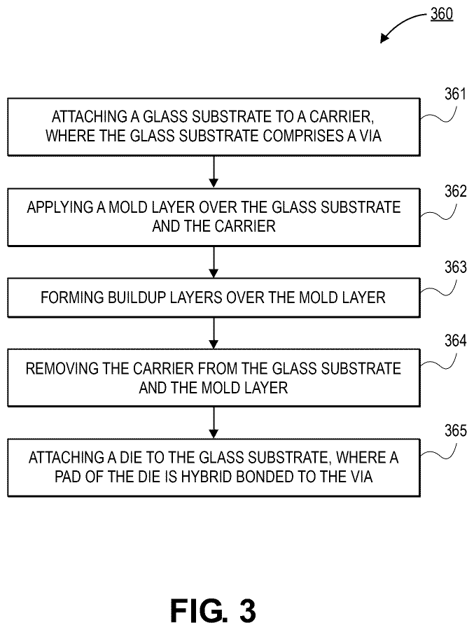

Referring now to FIG. 3, a flow diagram of a process 360 for forming a package substrate with an embedded glass core is shown, in accordance with an embodiment. In an embodiment, the package substrate formed with process 360 may be similar to any of the package substrates described in greater detail herein.

In an embodiment, the process 360 may begin with operation 361, which comprises attaching a glass substrate to a carrier. In an embodiment, the glass substrate may comprise a via through a thickness of the glass substrate. The glass substrate may be similar to any of the glass cores described in greater detail herein. In an embodiment, the glass substrate may be coupled to the carrier by an adhesive layer or the like.

In an embodiment, the process 360 may continue with operation 362, which comprises applying a mold layer over the glass substrate and the carrier. In an embodiment, the mold layer may comprise an organic dielectric material. The mold layer may cover sidewall surfaces of the glass substrate and a top surface of the glass substrate opposite from the carrier.

In an embodiment, the process 360 may continue with operation 363, which comprises forming one or more buildup layers over the mold layer. In an embodiment, the one or more buildup layers may comprise electrical routing that is electrically coupled to the via in the glass substrate.

In an embodiment, the process 360 may continue with operation 364, which comprises removing the carrier from the glass substrate and the mold layer. In an embodiment, the carrier may be removed by releasing the adhesive layer with a suitable stimulus (e.g., heat, UV exposure, laser exposure, etc.).

In an embodiment, the process 360 may continue with operation 365, which comprises attaching a die to the glass substrate. In an embodiment, a pad of the die is hybrid bonded to the via. Though, in other embodiments any FLI architecture (e.g., solder or the like) may be used to couple the pad of the die to the via.

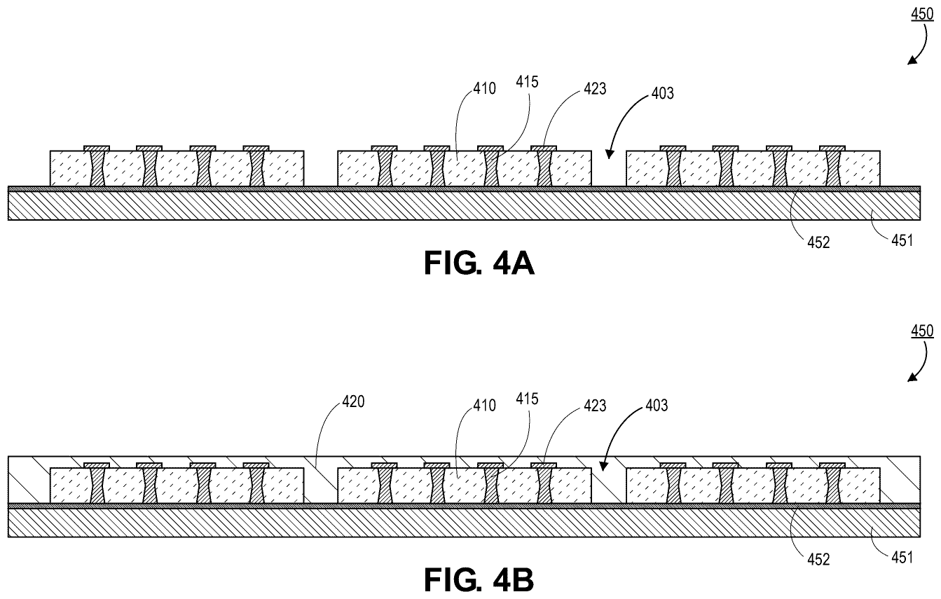

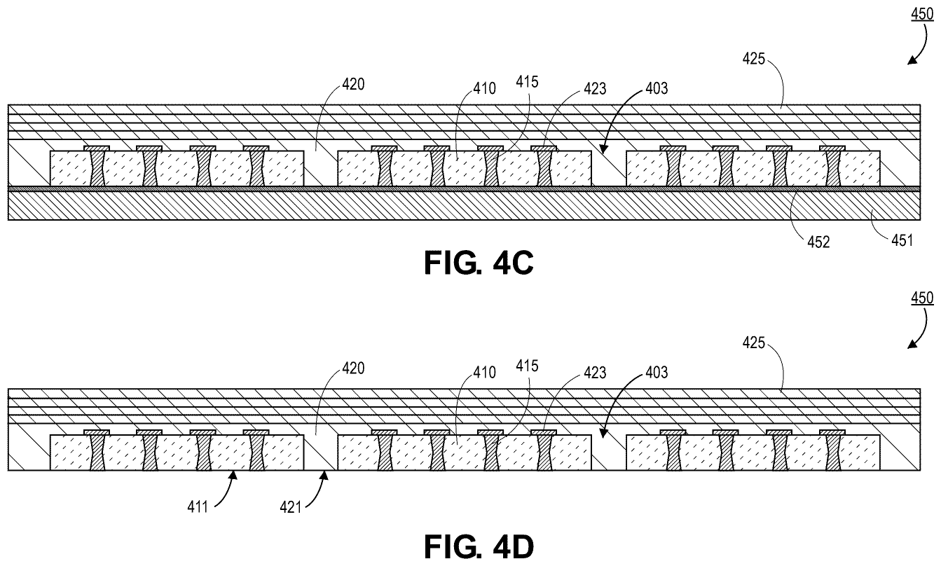

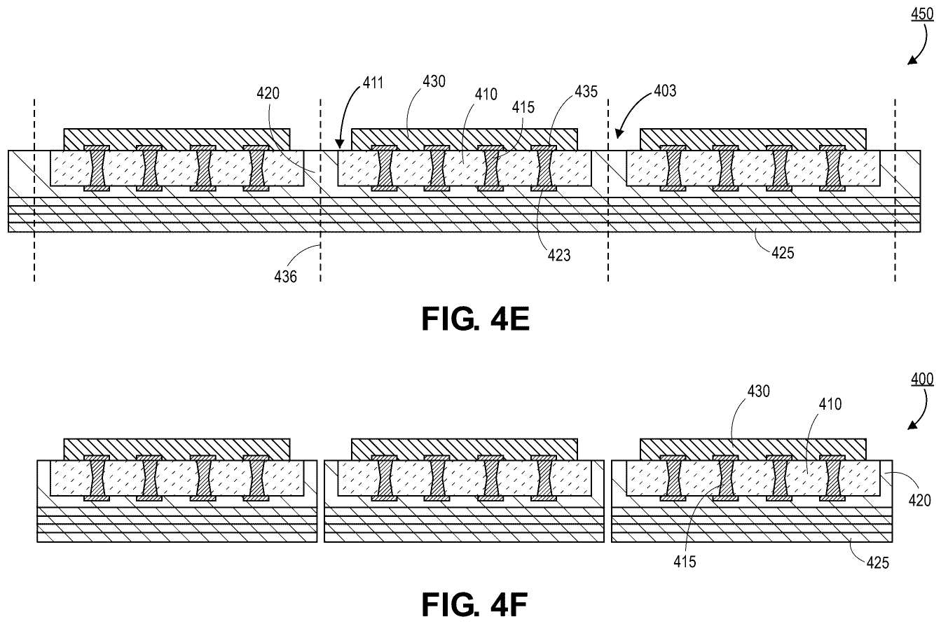

Referring now to FIGS. 4A-4F, a series of cross-sectional illustrations depicting a process for forming a package substrate 400 with a reconstituted panel process is shown, in accordance with an additional embodiment.

Referring now to FIG. 4A, a cross-sectional illustration of a reconstituted panel 450 at a stage of manufacture is shown, in accordance with an embodiment. In an embodiment, the reconstituted panel 450 may comprise a plurality of glass cores 410 that are attached to a carrier 451. For example, an adhesive layer 452 or the like may be used to couple the glass cores 410 to the carrier 451. In an embodiment, the carrier 451 may comprise an inorganic material, such as a metal plate, a glass plate, a ceramic plate, or the like. The glass cores 410 may be spaced apart from each other by a gap 403. In an embodiment, the glass cores 410 may be similar to any of the glass cores described in greater detail herein.

In an embodiment, vias 415 may be formed through the glass core 410. The vias 415 may be similar to any of the through glass vias described in greater detail herein. In an embodiment, pads 423 may be formed over the glass cores 410 with a plating and patterning process or the like. The pads 423 may be aligned over the vias 415. Though, in other embodiments, the pads 423 may be omitted.

Referring now to FIG. 4B, a cross-sectional illustration of the reconstituted panel 450 after a mold layer 420 is applied over the glass cores 410 is shown, in accordance with an embodiment. In an embodiment, the mold layer 420 may be an organic dielectric material, such as an epoxy, a buildup film, or the like. In an embodiment, the mold layer 420 may fill the gaps 403 between the glass cores 410. The mold layer 420 may cover the top surfaces of the glass cores 410 as well.

Referring now to FIG. 4C, a cross-sectional illustration of the reconstituted panel 450 after one or more buildup layers 425 are formed over the mold layer 420 is shown, in accordance with an embodiment. In the illustrated embodiment, four buildup layers 425 are shown as one example. Though, embodiments may include any number of buildup layers 425. For example, there may be up to six buildup layers 425 provided over the mold layer 420 in some embodiments. In an embodiment, the buildup layers 425 may comprise an organic dielectric material, such as a buildup film or the like. In an embodiment, the buildup layers 425 may comprise a different material than the mold layer 420. Though, in other embodiments, the mold layer 420 and the buildup layers 425 may comprise the same or similar material. For example, the mold layer 420 and the buildup layers 425 may both comprise a buildup film in some embodiments.

In an embodiment, electrically conductive routing (not shown) may be provide in the buildup layers 425. The buildup layers 425 and the electrically conductive routing may be formed with any suitable process, such as an SAP process or the like. In an embodiment, the electrically conductive routing of the buildup layers 425 may be electrically coupled to the pads 423 (or the vias 415 in the glass core 410).

Referring now to FIG. 4D, a cross-sectional illustration of the reconstituted panel 450 after the carrier 451 is removed is shown, in accordance with an embodiment. In an embodiment, the carrier 451 may be removed by deactivating the adhesive layer 452. For example, a thermal release, a UV exposure release, a laser release, or the like may be used in order to deactivate the adhesive layer 452. Removal of the carrier 451 exposes a first surface 411 of the glass core 410 and a surface 421 of the mold layer 420. Since the mold layer 420 and the glass core 410 were both pressed against the same planar surface of the carrier 451, the first surface 411 of the glass core 410 and the surface 421 of the mold layer 420 may be substantially coplanar with each other.

Referring now to FIG. 4E, a cross-sectional illustration of the reconstituted panel 450 after a die 430 is mounted to each of the glass cores 410 is shown, in accordance with an embodiment. In the illustrated embodiment, pads 435 of the dies 430 are hybrid bonded to the vias 415 of the glass cores 410. Accordingly, there may not be any routing layers between the dies 430 and the glass cores 410 in some embodiments. In other embodiments, the dies 430 may be coupled to the vias 415 with any suitable FLI architecture, such as solder balls or the like.

Referring now to FIG. 4F, a cross-sectional illustration of a plurality of package substrates 400 that are singulated from the reconstituted panel 450 is shown, in accordance with an embodiment. In an embodiment, singulation may occur along the cut lines 436 shown in FIG. 4E. The cut lines 436 may be outside of the glass core 410. For example, the cut lines 436 may pass through the gaps 403 between the glass cores 410 Accordingly, portions of the mold layer 420 remain along the sidewalls of the glass core 410. Further, the singulation process may not need to pass through any glass, which further protects the glass cores 410 from damage and makes the singulation process less complex. The singulation process may include a mechanical sawing process, a laser ablation process, an etching process, or the like.

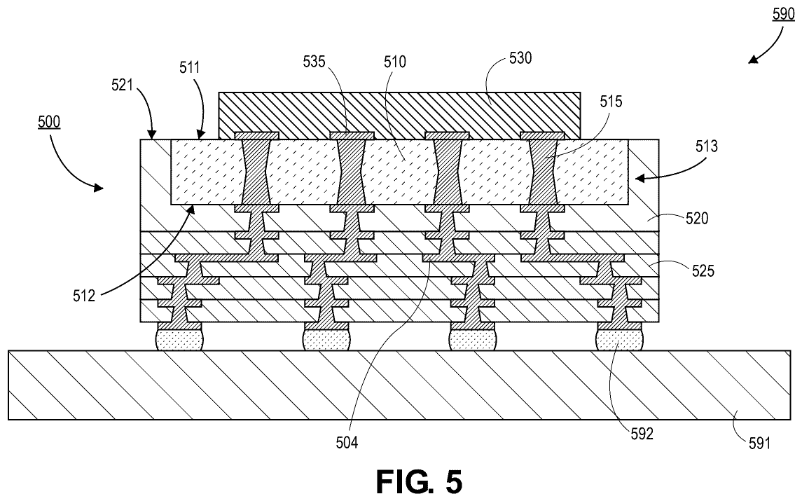

Referring now to FIG. 5, a cross-sectional illustration of an electronic system 590 is shown, in accordance with an embodiment. In an embodiment, the electronic system 590 may comprise a board 591. The board 591 may be a printed circuit board (PCB), a motherboard, and/or the like. In an embodiment, the board 591 is coupled to a package substrate 500 by interconnects 592. The interconnects 592 may include any suitable second level interconnect (SLI) architecture. For example, the interconnects 592 may comprise solder balls, sockets, pins, and/or the like.

In an embodiment, the package substrate 500 may be similar to any of the package substrates described in greater detail herein. For example, the package substrate 500 may comprise a glass core 510 with vias 515. The glass core 510 may be surrounded by a mold layer 520. As shown, the mold layer 520 covers a second surface 512 of the glass core 510 and sidewalls surfaces 513 of the glass core. A first surface 511 of the glass core 510 and a surface 521 of the mold layer 520 may be substantially coplanar with each other. In an embodiment, one or more buildup layers 525 may be provided between the mold layer 520 and the board 591. The one or more buildup layers 525 may comprise electrical routing 504 (e.g., pads, traces, vias, etc.) that electrically couple the vias 515 to the interconnects 592.

In an embodiment, the electronic system 590 may further comprise one or more dies 530 that are coupled to vias 515 of the glass core 510. In an embodiment, pads 535 of the die 530 are hybrid bonded to the vias 515. Though, in other embodiments and FLI architecture may be used to couple the die 530 to the vias 515 of the package substrate 500. In an embodiment, the dies 530 may comprise any suitable type of die, such as a processor (e.g., a central processing unit (CPU), a graphics processing unit (GPU), etc.), a memory die, a communications die, and/or the like.

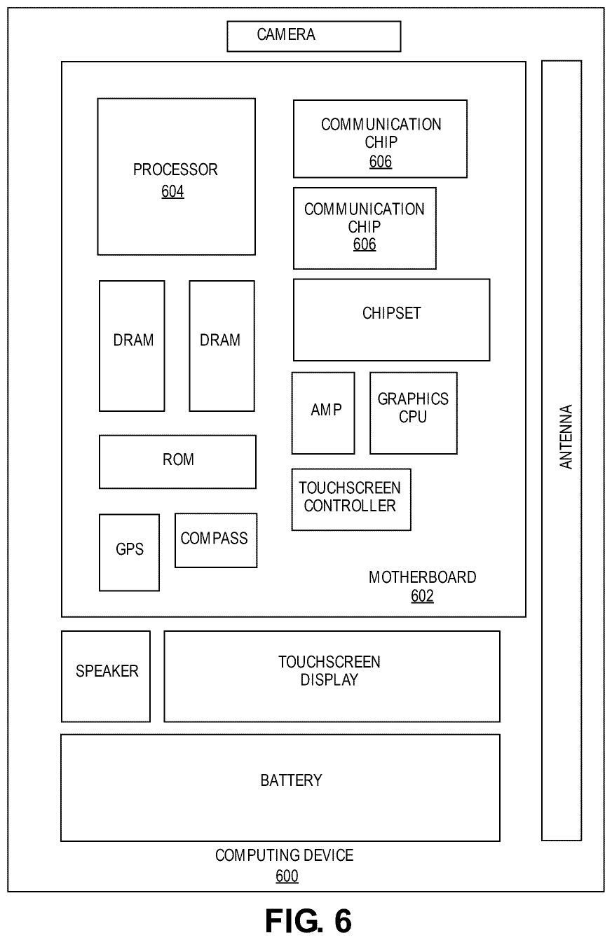

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of an electronic package that comprises a glass core that is embedded within a mold layer and includes buildup layers on only one side of the glass core, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of an electronic package that comprises a glass core that is embedded within a mold layer and includes buildup layers on only one side of the glass core, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, wherein the substrate comprises a glass layer with a first surface, a second surface, and a sidewall surface; a via through a thickness of the substrate; a first layer on the substrate, wherein the first layer is over the first surface and the sidewall surface of the substrate, and wherein the first layer comprises a first organic dielectric material; a second layer spaced apart from the substrate by the first layer, wherein the second layer comprises a second organic dielectric material; and a die over the second surface of the substrate, wherein the die is hybrid bonded to the via.

Example 2: the apparatus of Example 1, wherein the first organic dielectric material is different than the second organic dielectric material.

Example 3: the apparatus of Example 2, wherein the first organic dielectric material comprises an epoxy, and wherein the second organic dielectric material comprises a buildup film.

Example 4: the apparatus of Examples 1-3, wherein at least a portion of the second surface of the substrate is exposed.

Example 5: the apparatus of Examples 1-4, wherein the die has a first width and the substrate has a second width that is different than the first width.

Example 6: the apparatus of Examples 1-5, wherein the first layer has an exposed surface facing away from the second layer, and wherein the exposed surface is scalloped.

Example 7: the apparatus of Example 6, wherein a fiber extends out from the first layer beyond the exposed surface.

Example 8: the apparatus of Examples 1-7, further comprising electrical routing within the second layer, and wherein the electrical routing is electrically coupled to the via by a second via through a portion of the first layer.

Example 9: the apparatus of Examples 1-8, further comprising: a second die on the substrate, wherein the second die is hybrid bonded to a second via through the substrate, and wherein the second die is electrically coupled to the die by electrical routing within the first layer and/or the second layer.

Example 10: the apparatus of Examples 1-9, further comprising a board coupled to the second layer.

Example 11: an apparatus, comprising: a substrate, wherein the substrate comprises a glass layer; a first via through a thickness of the substrate; a pad on the substrate over the first via; a first layer on a first surface of the substrate, wherein the first layer comprises an organic molding material; a second via through at least a portion of the first layer; a second layer on the first layer, wherein the second layer comprises an organic buildup film; and electrically conductive routing within the second layer, wherein the electrically conductive routing is electrically coupled to the second via.

Example 12: the apparatus of Example 11, wherein the first layer covers a sidewall of the substrate.

Example 13: the apparatus of Example 12, wherein a surface of the first layer is non-planar.

Example 14: the apparatus of Example 12 or Example 13, wherein a plurality of fibers extend past a surface of the first layer.

Example 15: the apparatus of Examples 11-14, further comprising: a die electrically coupled to the first via, wherein the die is on an opposite side of the substrate from the first layer.

Example 16: the apparatus of Example 15, wherein the die is hybrid bonded to the first via.

Example 17: an apparatus, comprising: a plurality of glass cores; a mold layer over the plurality of glass cores, wherein the mold layer fills gaps between the plurality of the glass cores; a buildup layer over the mold layer; and a plurality of dies, wherein each of the plurality of dies is hybrid bonded to a different one of the plurality of glass cores.

Example 18: the apparatus of Example 17, wherein surfaces of the plurality of glass cores are exposed.

Example 19: the apparatus of Example 17 or Example 18, wherein the plurality of glass cores each have a first width, and wherein the plurality of dies each have a second width that is smaller than the first width.

Example 20: the apparatus of Examples 17-19, wherein the mold layer comprises a scalloped surface.

What is claimed is:

1. An apparatus, comprising:
a substrate, wherein the substrate comprises a glass layer with a first surface, a second surface, and a sidewall surface;
a via through a thickness of the substrate;
a first layer on the substrate, wherein the first layer is over the first surface and the sidewall surface of the substrate, and wherein the first layer comprises a first organic dielectric material;
a second layer spaced apart from the substrate by the first layer, wherein the second layer comprises a second organic dielectric material; and
a die over the second surface of the substrate, wherein the die is hybrid bonded to the via.

2. The apparatus of claim 1, wherein the first organic dielectric material is different than the second organic dielectric material.

3. The apparatus of claim 2, wherein the first organic dielectric material comprises an epoxy, and wherein the second organic dielectric material comprises a buildup film.

4. The apparatus of claim 1, wherein at least a portion of the second surface of the substrate is exposed.

5. The apparatus of claim 1, wherein the die has a first width and the substrate has a second width that is different than the first width.

6. The apparatus of claim 1, wherein the first layer has an exposed surface facing away from the second layer, and wherein the exposed surface is scalloped.

7. The apparatus of claim 6, wherein a fiber extends out from the first layer beyond the exposed surface.

8. The apparatus of claim 1, further comprising electrical routing within the second layer, and wherein the electrical routing is electrically coupled to the via by a second via through a portion of the first layer.

9. The apparatus of claim 1, further comprising:
a second die on the substrate, wherein the second die is hybrid bonded to a second via through the substrate, and wherein the second die is electrically coupled to the die by electrical routing within the first layer and/or the second layer.

10. The apparatus of claim 1, further comprising a board coupled to the second layer.

11. An apparatus, comprising:
a substrate, wherein the substrate comprises a glass layer;
a first via through a thickness of the substrate;
a pad on the substrate over the first via;
a first layer on a first surface of the substrate, wherein the first layer comprises an organic molding material;
a second via through at least a portion of the first layer;
a second layer on the first layer, wherein the second layer comprises an organic buildup film; and
electrically conductive routing within the second layer, wherein the electrically conductive routing is electrically coupled to the second via.

12. The apparatus of claim 11, wherein the first layer covers a sidewall of the substrate.

13. The apparatus of claim 12, wherein a surface of the first layer is non-planar.

14. The apparatus of claim 12, wherein a plurality of fibers extend past a surface of the first layer.

15. The apparatus of claim 11, further comprising:
a die electrically coupled to the first via, wherein the die is on an opposite side of the substrate from the first layer.

16. The apparatus of claim 15, wherein the die is hybrid bonded to the first via.

17. An apparatus, comprising:
a plurality of glass cores;
a mold layer over the plurality of glass cores, wherein the mold layer fills gaps between the plurality of the glass cores;
a buildup layer over the mold layer; and
a plurality of dies, wherein each of the plurality of dies is hybrid bonded to a different one of the plurality of glass cores.

18. The apparatus of claim 17, wherein surfaces of the plurality of glass cores are exposed.

19. The apparatus of claim 17, wherein the plurality of glass cores each have a first width, and wherein the plurality of dies each have a second width that is smaller than the first width.

20. The apparatus of claim 17, wherein the mold layer comprises a scalloped surface.
